(19) United States
(12) Patent Application Publication
(10) Pub. No.: US 2022/0115840 A1
(43) Pub. Date: Apr. 14, 2022

(54) MEASUREMENT METHOD, MANUFACTURING METHOD, MEASUREMENT APPARATUS OF SURFACE-EMITTING LASER, AND NON-TRANSITORY STORAGE MEDIUM STORING MEASUREMENT PROGRAM OF SURFACE-EMITTING LASER

(71) Applicant: SUMITOMO ELECTRIC INDUSTRIES, LTD., Osaka-shi (JP)

(72) Inventor: Ryosuke KUBOTA, Osaka-shi (JP)

(73) Assignee: SUMITOMO ELECTRIC INDUSTRIES, LTD., Osaka-shi (JP)

(21) Appl. No.: 17/493,325

(22) Filed: Oct. 4, 2021

(30) Foreign Application Priority Data
Oct. 8, 2020 (JP) 2020-170767

(51) Int. Cl. H01S 5/183; H01S 5/42

(52) U.S. Cl. CPC H01S 5/18394; H01S 5/423; H01S 5/18388

(57) ABSTRACT

A measurement method of a surface-emitting laser includes a step of causing a surface-emitting laser to emit light and a step of positioning an optical axis of an optical system on each of a plurality of positions of the surface-emitting laser and measuring a spectrum at each of the plurality of positions.

### CROSS REFERENCE TO RELATED APPLICATIONS

This application claims priority based on Japanese Patent Application No. 2020-170767, filed on Oct. 8, 2020, and the entire contents of the Japanese patent application are incorporated herein by reference.

### FIELD OF THE INVENTION

The present disclosure relates to a measurement method, a manufacturing method, a measurement apparatus of a surface-emitting laser, and a non-transitory storage medium storing the measurement program of the surface-emitting laser.

### BACKGROUND ART

To evaluate characteristics of a surface-emitting laser (vertical cavity surface-emitting laser), a spectrum of light is measured in some cases (for example, Japanese Unexamined Patent Application Publication No. 2000-12969).

### SUMMARY OF THE INVENTION

A measurement method of a surface-emitting laser according to the present disclosure includes a step of causing a surface-emitting laser to emit light and a step of positioning an optical axis of an optical system on each of a plurality of positions of the surface-emitting laser and measuring a spectrum at each of the plurality of positions.

A manufacturing method of a surface-emitting laser according to the present disclosure includes forming a surface-emitting laser and performing the above-mentioned measurement method on the surface-emitting laser.

A measurement apparatus of a surface-emitting laser according to the present disclosure includes a light-emitter configured to cause a surface-emitting laser to emit light and a measurer configured to measure a spectrum at each of a plurality of positions of the surface-emitting laser.

A non-transitory storage medium stores measurement program executable by a computer for measuring optical characteristics of a surface-emitting laser. The program causes the computer to perform a process. The process includes causing a surface-emitting laser to emit light, and positioning an optical axis of an optical system on each of a plurality of positions of the surface-emitting laser and measuring a spectrum at each of the plurality of positions.

### BRIEF DESCRIPTION OF THE DRAWINGS

FIG. 1A is a schematic diagram illustrating a measurement apparatus according to an embodiment.

FIG. 1B is a block diagram illustrating a hardware configuration of a control part.

FIG. 2 is a plan view illustrating a wafer.

FIG. 3A is a plan view illustrating a surface-emitting laser.

FIG. 3B is an enlarged view of an aperture.

FIG. 4 is a flowchart illustrating a manufacturing method of a surface-emitting laser.

FIG. 5 is a flow chart illustrating a measurement method of characteristics.

FIG. 6A is a diagram illustrating an example of a spectrum.

FIG. 6B is a diagram illustrating an example of a spectrum.

FIG. 6C is a diagram illustrating an example of a spectrum.

FIG. 7A is a diagram illustrating an example of an NFP.

FIG. 7B is a diagram illustrating an example of an NFP.

FIG. 7C is a diagram illustrating an example of an NFP.

### DESCRIPTION OF EMBODIMENTS

In order to evaluate characteristics of a surface-emitting laser, it is important to measure an accurate spectrum of emitted light. A surface-emitting laser has a larger light output surface (aperture) than an edge-emitting laser or the like. The light has, for example, a plurality of transverse modes and is distributed in the aperture. Therefore, it has been difficult to measure an accurate spectrum. Therefore, it is an object of the present disclosure to provide a measurement method, a manufacturing method and a measurement apparatus of a surface-emitting laser, and a non-transitory storage medium storing the measurement program of the surface-emitting laser that can measure an accurate spectrum of light of the surface-emitting laser.

First, the contents of embodiments according to the present disclosure will be listed and described.

(1) One aspect of the present disclosure is a measurement method of a surface-emitting laser including a step of causing a surface-emitting laser to emit light, and a step of positioning an optical axis of an optical system on each of a plurality of positions of the surface-emitting laser and measuring a spectrum at each of the plurality of positions. By performing the measurement at each of the plurality of positions, it is possible to accurately measure the spectrum of the light of the surface-emitting laser.

(2) The plurality of positions may include an entire portion of an aperture of the surface-emitting laser. An accurate spectrum can be measured from the entire emitted light of the aperture.

(3) The measurement method may further include a step of acquiring, based on the spectra at the plurality of positions, emission intensities of respective wavelengths of light at the plurality of positions. Wavelength-resolved local emission intensities can be acquired.

(4) The measurement method may further include a step of generating, based on the emission intensities, a near field pattern of the surface-emitting laser. The near field pattern makes it easy to recognize a light distribution.

(5) The step of causing the surface-emitting laser to emit light may include a step of causing the surface-emitting laser to emit light by inputting an electric signal to the surface-emitting laser. A more accurate spectrum can be measured by causing the surface-emitting laser to emit light under conditions close to those at the time of use.

(6) The step of measuring the spectrum may include changing the electric signal to generate a plurality of electric signals and measuring a spectrum at each of the plurality of positions of the surface-emitting laser in accordance with each of the plurality of electric signals. A more accurate spectrum can be measured.

(7) The optical system may include a measurer configured to measure the spectrum, an optical fiber connected to the measurer, and a first lens and a second lens disposed in order between the optical fiber and the surface-emitting laser. In the optical system, the second lens may have a larger numerical aperture than the first lens. Light is condensed for each position of the surface-emitting laser by the first lens and the second lens, and an accurate spectrum of the light of the surface-emitting laser can be measured.

(8) A manufacturing method of a surface-emitting laser includes forming a surface-emitting laser and performing the measurement method of the surface-emitting laser described above on the surface-emitting laser. By performing the measurement at each of the plurality of positions, it is possible to accurately measure the spectrum of the light of the surface-emitting laser.

(9) A measurement apparatus of a surface-emitting laser includes a light-emitter configured to cause a surface-emitting laser to emit light and a measurer configured to measure a spectrum at each of a plurality of positions of the surface-emitting laser. By performing the measurement at each of the plurality of positions, it is possible to accurately measure the spectrum of the light of the surface-emitting laser.

(10) The measurement apparatus of a surface-emitting laser may further include an optical fiber connected to the measurer and a first lens and a second lens disposed in order between the optical fiber and the surface-emitting laser. In the measurement apparatus, the second lens may have a larger numerical aperture than the first lens. Light is condensed for each position of the surface-emitting laser by the first lens and the second lens, and an accurate spectrum of the light of the surface-emitting laser can be measured.

(11) A non-transitory storage medium stores a measurement program executable by a computer for measuring optical characteristics of a surface-emitting laser. The program causes the computer to perform a process. The process includes causing a surface-emitting laser to emit light, and positioning an optical axis of an optical system on each of a plurality of positions of the surface-emitting laser and measuring a spectrum at each of the plurality of positions. By performing the measurement at each of the plurality of positions, it is possible to accurately measure the spectrum of the light of the surface-emitting laser.

### Details of Embodiments of the Present Disclosure

Specific examples of a measurement method, a manufacturing method and a measurement apparatus of a surface-emitting laser, and a non-transitory storage medium storing a measurement program of the surface-emitting laser according to an embodiment of the present disclosure will be described below with reference to the drawings. It should be noted that the present disclosure is not limited to these examples, and is defined by claims, and is intended to embrace all the modifications within the meaning and range of equivalency of the claims.

### (Measurement Apparatus)

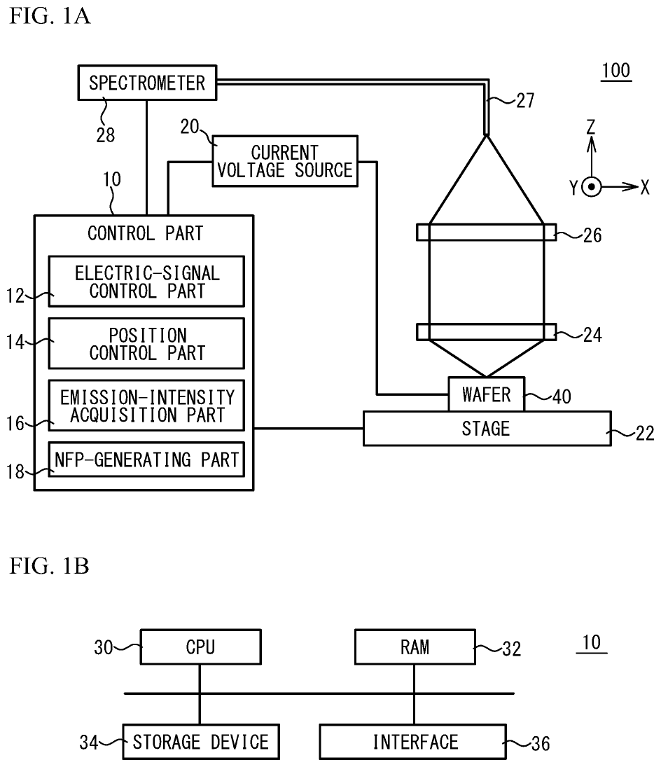

FIG. 1A is a schematic diagram illustrating a measurement apparatus 100 according to an embodiment. As illustrated in FIG. 1A, measurement apparatus 100 includes a control part 10, a current voltage source 20, a stage 22, lenses 24 and 26, an optical fiber 27, and a spectrometer 28 (a measurer).

A main surface of stage 22 is located in an XY plane. A normal direction of the main surface of stage 22 is a Z-axis direction. An X-axis direction, a Y-axis direction, and the Z-axis direction are orthogonal to each other. A wafer 40 is disposed on the main surface of stage 22. Stage 22 is movable, and can change the position of wafer 40 in the XY plane and the height of wafer 40 in the Z-axis direction. Stage 22 may have a function to regulate a temperature of wafer 40. Current voltage source 20 inputs an electric signal (current) to the surface-emitting laser in wafer 40 through probes (not illustrated).

An optical system includes lenses 24 and 26, optical fiber 27, and spectrometer 28 to measure a spectrum. Optical axes of lenses 24 and 26 extend in the Z-axis direction. Lenses 24 and 26 and optical fiber 27 are arranged in this order in the Z-axis direction from wafer 40. Lenses 24 and 26 are condenser lenses. Lens 24 has a higher numerical aperture (NA) and a higher space resolution than lens 26. Lens 26 has a lower NA and a lower space resolution than lens 24. An NA of lens 24 is, for example, from 0.7 to 0.8. An NA of lens 26 is 0.2, for example.

Optical fiber 27 is, for example, a single-mode fiber having a core diameter of 2 μm to 8 μm. One end of optical fiber 27 faces lens 26, and the other end thereof is connected to spectrometer 28. Spectrometer 28 measures a spectrum of light inputted through optical fiber 27. A spectrum analyzer may be used instead of spectrometer 28. Spectrometer 28 takes 100 ms to measure one spectrum. Spectrum analyzer takes one second to measure one spectrum.

FIG. 1B is a block diagram illustrating a hardware configuration of control part 10. As illustrated in FIG. 1B, control part 10 includes a central processing unit (CPU) 30, a random access memory (RAM) 32, a storage device 34, and an interface 36. CPU 30, RAM 32, storage device 34, and interface 36 are connected to each other by buses or the like. RAM 32 is a volatile memory that temporarily stores programs, data and the like. Storage device 34 is, for example, a read only memory (ROM), a solid state drive (SSD) such as a flash memory, or a hard disc drive (HDD). Storage device 34 stores a measurement program and the like, which will be described later.

CPU 30 executes a program stored in RAM 32, thereby realizing an electric-signal control part 12, a position control part 14, an emission-intensity acquisition part 16, an NFP-generating part 18, and the like illustrated in FIG. 1A in control part 10. Each part of control part 10 may be a hardware such as a circuit. Electric-signal control part 12 controls current voltage source 20 to turn on/off and change a current inputted to wafer 40. Position control part 14 controls stage 22 to adjust a position of wafer 40. Emission-intensity acquisition part 16 acquires a spectrum of light measured by spectrometer 28, and acquires an emission intensity of surface-emitting laser 41 based on the spectrum. NFP-generating part 18 generates an NFP (Near Field Pattern) based on the emission intensities.

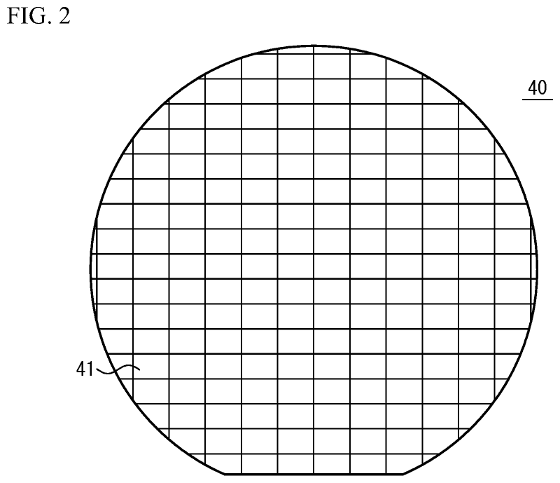

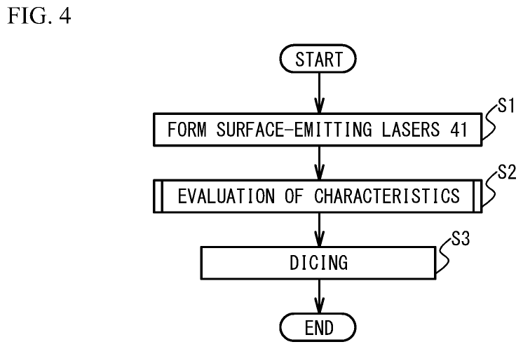

FIG. 2 is a plan view illustrating wafer 40. Wafer 40 has, for example, several tens of thousands of surface-emitting lasers 41. A measurement of characteristics described later with reference to FIG. 4 is performed for each of surface-emitting lasers 41 in wafer 40.

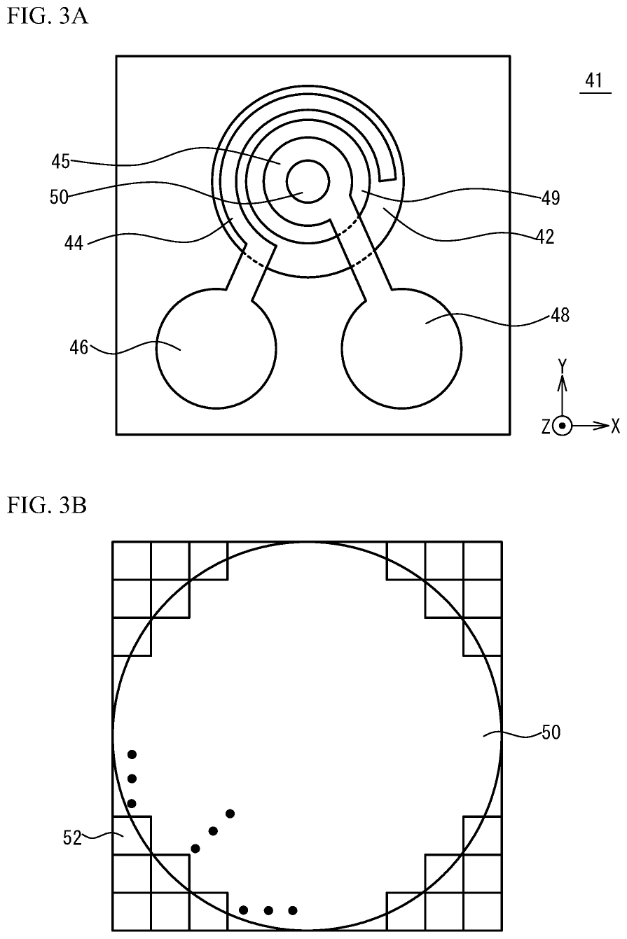

FIG. 3A is a plan view illustrating surface-emitting laser 41. As illustrated in FIG. 3A, surface-emitting laser 41 includes a mesa 49, electrodes 44 and 45, and pads 46 and 48. Surface-emitting laser 41 is formed of, for example, a compound semiconductor, and includes a lower cladding layer, a core layer, and an upper cladding layer that are stacked. The lower cladding layer is formed of, for example, n-type aluminum gallium arsenide (n-AlGaAs). The upper cladding layer is formed of, for example, p-AlGaAs. The core layer is formed of indium gallium arsenide (InGaAs) or the like and has a multi quantum well (MQW) structure.

An aperture 50 is formed in mesa 49 and serves as an output portion of light. A groove 42 is provided around mesa 49 in the XY plane. Electrode 44 is provided inside groove 42 and electrically connected to pad 46 and the lower cladding layer. Electrode 45 is provided on mesa 49 and electrically connected to pad 48 and the upper cladding layer. Electrode 44 is formed of, for example, a stacked body of titanium, platinum, and gold (Ti/Pt/Au). Electrode 45 is formed of, for example, gold-germanium alloy (Au—Ge alloy). Pads 46 and 48 are formed of a metal such as gold (Au).

FIG. 3B is an enlarged view of aperture 50. Aperture 50 has a circular shape with a diameter of 20 μm, for example. Positions 52 are regions where a spectrum is measured. Each of positions 52 is, for example, a square having a one side length of 500 nm. For example, 40 positions 52 are arranged in one row in the X-axis direction. The plurality of positions 52 include an entire portion of aperture 50. That is, the plurality of positions 52 cover the entire portion of aperture 50. Some of the plurality of positions 52 may be located outside aperture 50.

Current voltage source 20 in FIG. 1A is connected to pads 46 and 48 of surface-emitting laser 41 to input an electric signal to surface-emitting laser 41. By injecting carriers into the core layer of surface-emitting laser 41, light having a wavelength from 800 nm to 1000 nm, for example, is emitted from aperture 50 in the Z-axis direction. The light includes a plurality of transverse modes, for example, and is distributed in aperture 50. Differences occur in the wavelength and emission intensity of the light depending on a position and other factors. In this embodiment, a local spectrum in aperture 50 is measured.

Spectrometer 28 illustrated in FIG. 1A measures a spectrum of light at each of positions 52. Emission-intensity acquisition part 16 of control part 10 acquires an emission intensity at each of positions 52 based on the spectrum. Emission-intensity acquisition part 16 acquires an emission intensity over the entire wavelength range (for example, from 800 nm to 1000 nm) of emitted light and an emission intensity at a specific wavelength of emitted light. NFP-generating part 18 generates an NFP based on the emission intensities. The measurement of the spectrum and the generation of the NFP will be described later.

### (Manufacturing Method and Measurement Method)

FIG. 4 is a flow chart illustrating a manufacturing method of the surface-emitting laser. As illustrated in FIG. 4, a plurality of surface-emitting lasers 41 are formed on wafer 40 (step S1). Specifically, metal organic chemical vapor deposition (MOCVD) is performed to epitaxially grow a lower cladding layer, a core layer, an upper cladding layer, and the like on wafer 40. Mesa 49 or the like is formed by etching or the like. For example, grooves are formed in a conductive semiconductor layer by etching or the like to electrically isolate the plurality of surface-emitting lasers 41 on wafer 40 from each other. Electrodes 44 and 45, and pads 46 and 48 are formed by resist patterning, vapor deposition and the like. After surface-emitting laser 41 is formed, characteristics of surface-emitting laser 41 are evaluated (step S2 in FIG. 4). After the evaluation, wafer 40 is diced (step S3).

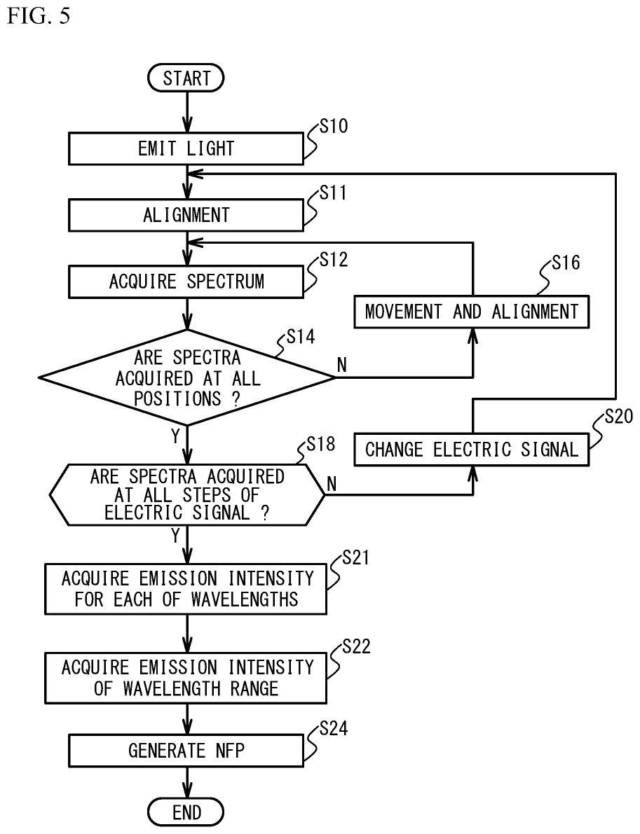

FIG. 5 is a flowchart illustrating a measurement method of characteristics of surface-emitting laser 41. The measurement of the characteristics is step S2 of FIG. 4, and is performed for one surface-emitting laser 41 included in wafer 40. As illustrated in FIG. 5, electric-signal control part 12 of control part 10 inputs an electric signal to surface-emitting laser 41 by using current voltage source 20 and causes surface-emitting laser 41 to emit light (step S10). Position control part 14 moves wafer 40 by stage 22 to align surface-emitting laser 41 with lenses 24 and 26 (step S11). Specifically, one of the plurality of positions 52 of surface-emitting laser 41 is positioned under lenses 24 and 26, and is aligned with the optical axis. Also in the Z-axis direction, the one position 52 is aligned with lenses 24 and 26. Lens 24 is focused on the one position 52, and lens 26 is focused on optical fiber 27.

Light from the one position 52 is focused by lenses 24 and 26, and enters spectrometer 28 through optical fiber 27. Lights from other positions 52 are not inputted to optical fiber 27 and spectrometer 28. Spectrometer 28 measures a spectrum of the light emitted from the one position 52, and control part 10 acquires the spectrum (step S12).

Control part 10 determines whether the spectra are acquired at all of the plurality of positions 52 (step S14). In the case of “No”, position control part 14 moves wafer 40 using stage 22, and performs alignment between lenses 24, 26 and another position 52 different from the position 52 at which the spectrum has been measured among the plurality of positions 52 (step S16). Light from the another position 52 is inputted to spectrometer 28. Spectrometer 28 measures a spectrum, and control part 10 acquires the spectrum (step S12).

When spectra are acquired at all of the plurality of positions 52 (“Yes” in step S14), electric-signal control part 12 determines whether spectra are acquired at all steps of the electric signal (step S18). In the case of “No”, electric-signal control part 12 changes the electric signal (step S20). The processes of step S11 and subsequent steps are repeated to measure a spectrum at each of positions 52 while the changed electric signal is applied.

Electric-signal control part 12 changes a current in steps of 1 mA, for example, from 1 mA to 10 mA. After the spectra are acquired at all steps of the electrical signal (“Yes” in step S18), emission-intensity acquisition part 16 acquires an emission intensity for each of the wavelengths based on the spectra (step S21), and acquires an emission intensity of the entire wavelength range (step S22). NFP-generating part 18 generates an NFP based on the emission intensities (step S24). This completes the measurement.

After the measurement of FIG. 5 is performed on one of surface-emitting lasers 41 in wafer 40, the same measurement is performed on the other surface-emitting lasers 41. For example, the characteristics of all the surface-emitting lasers 41 in wafer 40 may be measured, or the characteristics of some of surface-emitting lasers 41 may be measured. After the measurement, wafer 40 is diced as illustrated in FIG. 4 (step S3). One surface-emitting laser 41 may be formed as a chip, or an array chip including a plurality of surface-emitting lasers 41 may be formed.

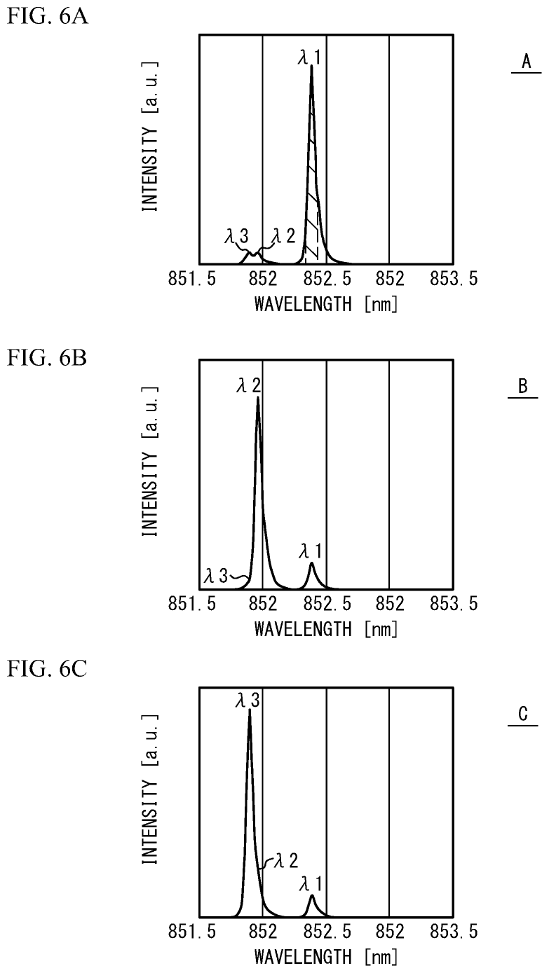

FIGS. 6A to 6C are diagrams illustrating examples of spectrum, and each of them illustrates the spectrum measured when a current I1 is inputted to surface-emitting laser 41. Current I1 is, for example, one of 1 mA, 2 mA, 3 mA, 4 mA, 5 mA, 6 mA, 7 mA, 8 mA, 9 mA, and 10 mA. FIG. 6A illustrates a spectrum measured at a position A. FIG. 6B illustrates a spectrum measured at a position B. FIG. 6C illustrates a spectrum measured at a position C. Each of positions A to C is one of the plurality of positions 52. In FIGS. 6A to 6C, a horizontal axis represents a wavelength of light, and a vertical axis represents an intensity of light. A wavelength λ1 is greater than 852 nm and less than 852.5 nm. A wavelength λ2 is less than 852 nm. A wavelength λ3 is greater than 851.5 nm and less than wavelength λ2.

The spectrum illustrated in FIG. 6A has a maximum peak at wavelength λ1 and small peaks at wavelengths λ2 and λ3. The spectrum illustrated in FIG. 6B has a maximum peak at wavelength λ2, a small peak at wavelength λ1, and no peak at wavelength λ3. The spectrum illustrated in FIG. 6C has a maximum peak at wavelength λ3, a small peak at wavelength λ1, and no peak at wavelength λ2. Measurement apparatus 100 measures the spectrum as illustrated in FIGS. 6A to 6C at each of the plurality of positions 52.

As indicated by diagonal lines in FIG. 6A, emission-intensity acquisition part 16 integrates a portion of the spectrum in a vicinity of wavelength λ1 to acquire an emission intensity at wavelength λ1 for each region (step S21 in FIG. 5). The vicinity of wavelength λ1 is, for example, a range of ±0.1 nm around λ1. In the same manner, emission-intensity acquisition part 16 also integrates portions of spectra in the vicinities of wavelengths λ2 and λ3 to acquire the respective emission intensities. NFP-generating part 18 generates an NFP that expresses the emission intensity in terms of, for example, brightness, color, or the like (step S24).

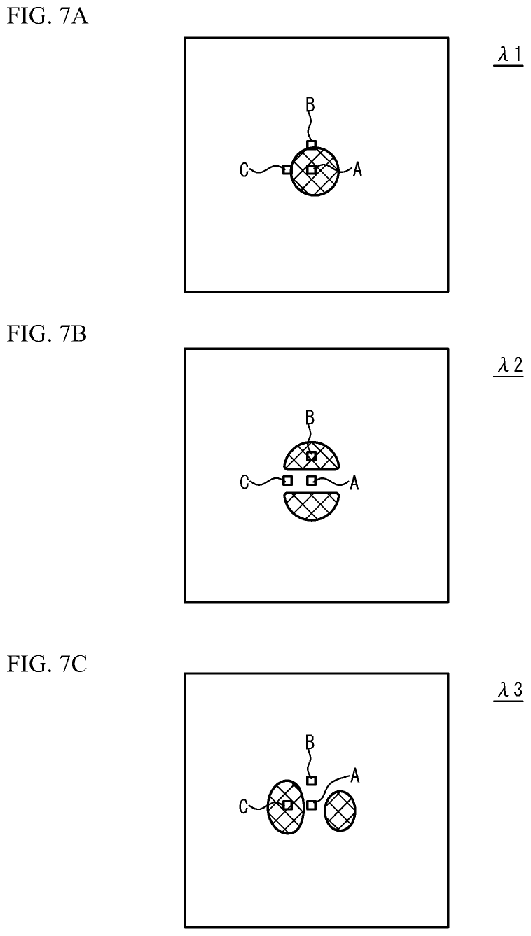

FIGS. 7A to 7C are diagrams illustrating examples of NFP. Positions A to C in FIGS. 7A to 7C are positions at which the spectra in FIGS. 6A to 6C are measured, respectively. Light is distributed in hatched portions in FIGS. 7A to 7C. FIG. 7A illustrates an NFP obtained from the emission intensities at wavelength λ1 in the spectra for the respective regions. As illustrated in FIG. 7A, light having wavelength λ1 is distributed in a circular shape in the center of surface-emitting laser 41. FIG. 7B illustrates an NFP obtained from the emission intensities at wavelength λ2 in the spectra for the respective regions. As illustrated in FIG. 7B, light having wavelength λ2 is distributed separately in a vertical direction of FIG. 7B, and overlaps position B, but does not overlap positions A and C. FIG. 7C illustrates an NFP obtained from the emission intensities at wavelength λ3 in the spectra for the respective regions. As illustrated in FIG. 7C, light having wavelength λ3 is distributed separately in a horizontal direction of FIG. 7C, and overlaps position C, but does not overlap positions A and B.

Emission-intensity acquisition part 16 may integrate a portion of spectrum at a wavelength other than wavelengths λ1 to λ3 to acquire an emission intensity for each wavelength. NFP-generating part 18 can also generate an NFP at a wavelength other than wavelengths λ1 to λ3. Emission-intensity acquisition part 16 can also acquire an emission intensity of the entire wavelength range by integrating the spectrum in the entire wavelength range (for example, a wavelength range from 800 nm to 1000 nm) (step S22). NFP-generating part 18 can also generate an NFP from the emission intensities of the entire wavelength range. The measurement apparatus 100 changes the electric signal (step S20 in FIG. 5), and acquires spectra and NFPs in the same manner as illustrated in FIGS. 6A to 7C.

According to the present embodiment, wafer 40 is moved to align each of the plurality of positions 52 of surface-emitting laser 41 with the optical axis of the optical system. The plurality of positions 52 are scanned, and a local spectrum at each of positions 52 is measured (step S12 in FIG. 5, and FIGS. 6A to 6C). An accurate spectrum can be measured from the emitted light including a plurality of transverse modes, and surface-emitting laser 41 can be evaluated with a high accuracy.

As illustrated in FIG. 3B, the plurality of positions 52 preferably includes the entire aperture 50. By measuring the spectrum at each of the plurality of positions 52, the accurate spectrum can be obtained from the entire emitted light of aperture 50. A size and number of positions 52 are determined according to, for example, a size of aperture 50, a resolution of lens, a measurement time, and the like.

Lenses 24 and 26 are disposed between surface-emitting laser 41 and optical fiber 27. Since lens 24 has a higher NA and a higher space resolution than lens 26, lens 24 can collect light emitted from one of the plurality of positions 52. Lens 26 narrows light from position 52 to be measured to a core diameter or less of optical fiber 27, and focuses light from position 52 not to be measured on the outside of optical fiber 27. Lenses 24 and 26 allow the emitted light from each of positions 52 to enter optical fiber 27 for accurate spectral measurement. Optical fiber 27 is preferably a single-mode fiber in order to allow the emitted light from one of positions 52 to enter and prevent unnecessary light from entering. Focal lengths of lenses 24 and 26, distances in the Z-axis direction between surface-emitting laser 41, lenses 24 and 26, and optical fiber 27, and the like are appropriately determined so that the emitted light from the one of positions 52 can be incident on optical fiber 27. Two or more lenses may be used, or a slit or the like may be used.

If the spectrum is measured without scanning the plurality of positions 52, it is difficult to obtain the accurate spectrum. For example, when the positional relationship between a lens having a high NA and surface-emitting laser 41 is fixed, the spectrum of the emitted light at one of positions 52 can be measured. However, it is difficult to measure the spectra at other positions. When only a lens having a low NA is used, it is difficult to measure a local spectrum because the space resolution of the lens is low. Since an area in which light can be collected is smaller than an area in which the emitted light of the surface-emitting laser 41 spreads, it is difficult to accurately measure the spectrum.

In this embodiment, the relative positions of surface-emitting laser 41 and lenses 24 and 26 are changed by moving wafer 40 using the stage 22. The plurality of positions 52 may be scanned to measure local spectra. Although the optical system such as lenses 24 and 26 and optical fiber 27 may be moved, it is preferable to move wafer 40 because a misalignment is likely to occur in the optical system.

Emission-intensity acquisition part 16 acquires the emission intensity at each of positions 52. For example, emission-intensity acquisition part 16 integrates portions of spectrum in the vicinities of specific wavelengths to acquire local emission intensities for the respective wavelengths (step S21). NFP-generating part 18 generates an NFP based on the emission intensities (step S24). A wavelength-resolved NFP as illustrated in FIGS. 7A to 7C makes it easy to recognize the emission intensity for each wavelength, so that surface-emitting laser 41 can be evaluated.

Emission-intensity acquisition part 16 integrates the spectrum over the entire wavelength range to acquire the emission intensity of the entire wavelength range (step S22). NFP-generating part 18 may represent the emission intensity of the entire wavelength range as the NFP. Control part 10 can also generate the spectrum of the entire aperture 50 by, for example, superimposing spectra for the plurality of positions 52. Surface-emitting laser 41 can be accurately evaluated by the spectrum and the NFP.

By inputting an electric signal from current voltage source 20 to surface-emitting laser 41, surface-emitting laser 41 is caused to emit light (step S10). The measurement is performed by causing surface-emitting laser 41 to emit light under conditions close to actual use of surface-emitting laser 41, as compared with light emission by photo excitation. Therefore, a more accurate spectrum can be measured.

A change in current inputted to surface-emitting laser 41 may change an oscillation mode of light or the like. For example, changing the current from I1 may change the spectrum and the NFP from the examples of FIGS. 6A to 7C. Electric-signal control part 12 changes the current in steps of 1 mA, for example, and spectrometer 28 measures the spectrum for each current. Emission-intensity acquisition part 16 acquires the emission intensity for each current, and NFP-generating part 18 generates the NFP. The change in the mode of light due to the electric signal can be measured.

A polarizer may be provided between lens 24 and lens 26. Only light having a specific polarization passes through the polarizer and enters spectrometer 28, so that a polarization dependence of the spectrum and the emission intensity can be obtained. A beam splitter may be provided between lens 24 and lens 26. One of light split by the beam splitter is incident on spectrometer 28, and the other of light is incident on the measuring instrument, so that other optical characteristics can be measured together with the spectrum.

In another embodiment, the characterization of surface-emitting laser 41 (step S2 in FIG. 4) may be performed after dicing wafer 40 (step S3). In this case, a step of bonding wires to pads 46 and 48 of surface-emitting laser 41 formed by dicing is performed before the evaluation. A chip of surface-emitting laser 41 is disposed on the main surface of stage 22. Current voltage source 20 inputs the electric signal (current) to surface-emitting laser 41 through wires. The measurement illustrated in the flow chart of FIG. 5 are performed on the chip. The array chip in which the plurality of surface-emitting lasers 41 are connected may be formed by dicing, and characteristics of the array chip may be measured.

Embodiments according to the present disclosure have been described above. However, the present invention is not limited to the embodiment described above, and various modifications and changes can be made to the present disclosure within the scope of the gist described in the claims.

What is claimed is:

1. A measurement method of a surface-emitting laser comprising:
causing a surface-emitting laser to emit light; and
positioning an optical axis of an optical system on each of a plurality of positions of the surface-emitting laser and measuring a spectrum at each of the plurality of positions.

2. The measurement method of a surface-emitting laser according to claim 1, wherein the plurality of positions include an entire portion of an aperture of the surface-emitting laser.

3. The measurement method of a surface-emitting laser according to claim 1, further comprising acquiring, based on the spectra at the plurality of positions, emission intensities of respective wavelengths of light at the plurality of positions.

4. The measurement method of a surface-emitting laser according to claim 3, further comprising generating, based on the emission intensities, a near field pattern of the surface-emitting laser.

5. The measurement method of a surface-emitting laser according to claim 1, wherein the causing a surface-emitting laser to emit light includes inputting an electric signal to the surface-emitting laser to cause the surface-emitting laser to emit light.

6. The measurement method of a surface-emitting laser according to claim 5, wherein the measuring the spectrum includes changing the electric signal to generate a plurality of electric signals and measuring a spectrum at each of the plurality of positions of the surface-emitting laser in accordance with each of the plurality of electric signals.

7. The measurement method of a surface-emitting laser according to claim 1, wherein
the optical system includes a measurer configured to measure the spectrum, an optical fiber connected to the measurer, and a first lens and a second lens disposed in order between the optical fiber and the surface-emitting laser, and
the second lens has a larger numerical aperture than the first lens.

8. A manufacturing method of a surface-emitting laser comprising:
forming a surface-emitting laser; and
performing the measurement method of a surface-emitting laser according to claim 1 on the surface-emitting laser.

9. A measurement apparatus of a surface-emitting laser comprising:
a light-emitter configured to cause a surface-emitting laser to emit light; and
a measurer configured to measure a spectrum at each of a plurality of positions of the surface-emitting laser.

10. The measurement apparatus of a surface-emitting laser according to claim 9, further comprising:
an optical fiber connected to the measurer; and
a first lens and a second lens disposed in order between the optical fiber and the surface-emitting laser, wherein
the second lens has a larger numerical aperture than the first lens.

11. A non-transitory storage medium storing a measurement program executable by a computer for measuring optical characteristics of a surface-emitting laser, the program causing the computer to perform a process, the process comprising:
causing a surface-emitting laser to emit light; and
positioning an optical axis of an optical system on each of a plurality of positions of the surface-emitting laser and measuring a spectrum at each of the plurality of positions.
